(19) United States
(12) Patent Application Publication
(10) Pub. No.: US 2013/0158912 A1
(43) Pub. Date: Jun. 20, 2013

(54) Apparatus for Measuring the State of Health of a Cell Pack

(71) Applicants: Jieh-Hwang Yen, Taoyuan County (TW); Fa-Hwa Shieh, Taoyuan County (TW); Wen-Chen Lih, Taoyuan County (TW); Kuo-Kuang Jen, Taoyuan County (TW); Ym-Min Liao, Taoyuan County (TW)

(72) Inventors: Jieh-Hwang Yen, Taoyuan County (TW); Fa-Hwa Shieh, Taoyuan County (TW); Wen-Chen Lih, Taoyuan County (TW); Kuo-Kuang Jen, Taoyuan County (TW); Ym-Min Liao, Taoyuan County (TW)

(73) Assignee: Chung-Shan Institute of Science and Technology, Armaments, Bureau, Ministry of National Defence, Taoyuan County (TW)

(21) Appl. No.: 13/326,437

(22) Filed: Dec. 15, 2011

(51) Int. Cl. G01R 31/36; G06F 17/18

(52) U.S. Cl. 702/63

(57) ABSTRACT

Disclosed is an apparatus for measuring and classifying a cell pack based on statistical parameters of charge of and discharge from the cell pack. The apparatus includes a control unit, a register, a database, a display, a charger and a load. The register, the database, the display, the charger and the load are connected to the control unit.

### BACKGROUND OF INVENTION

1. Field of Invention

The present invention relates to a method for measuring the state of health (“SOH”) of a cell pack and, more particularly, to a method for measuring the state of health of a cell pack by measuring charge of and discharge from the cell pack.

2. Related Prior Art

Conventionally, the SOH of a rechargeable Li—H cell pack is measured by DC impedance measurement or AC impedance measurement. In the DC impedance measurement, the transient change in the voltage of the cell pack is measured and divided by the current of the cell pack. Thus, the SOH of the cell pack is calculated. The DC impedance measurement however requires precise control over the power supply and the load. The DC impedance measurement further requires high-frequency signal-sampling. Hence, the cost is high. Moreover, the measured impedance often includes the impedance of a battery management system (“BMS”) and the impedance of a power MOS in addition to the impedance of the cell pack.

In the AC impedance measurement, the cell pack is provided with voltage (or current) of a small amplitude. Then, in a signal bandwidth such as 10 to 20 kHz, the frequency response of the current (or voltage) of the cell pack is measured, and an impedance relation is measured accordingly. With the measured impedance relation and the impedance of the cell pack at 1 KHz or in phase 0, the SOH of the cell pack is calculated. However, the AC impedance measurement needs a precise and stable voltage (or current) signal generator. The AC impedance measurement further requires a precise signal-measuring device for receiving response signals from the cell pack. To precisely measure the impedance, the demanding for contacts is harsh. Poor contacts affect the impedance measurement considerably. Hence, impedance measurement is executed on one cell at a time. That is, the cell pack has to be taken apart, and several rounds of impedance measurement have to be executed for all of the cells of the cell pack to finish the impedance measurement of the cell pack. As discussed above, the cost is high, and precision equipment is needed. Therefore, the AC impedance measure is not practical and is not suitable for large-scale implementation.

The present invention is therefore intended to obviate or at least alleviate the problems encountered in prior art.

### SUMMARY OF INVENTION

It is the primary objective of the present invention to provide a method for measuring the SOH of a cell pack by measuring the charge of and discharge from the cell pack.

To achieve the foregoing objective, the apparatus includes a control unit, a register, a database, a display, a charger and a load. The register, the database, the display, the charger and the load are connected to the control unit.

In an aspect, the control unit, the display, the charger and the load can be connected to the cell pack equipped with a battery management system. The control unit commands the charger to charge the cell pack, commands the load to receive electricity from the cell pack, reads the data via the battery management system, and registers the data in the register. The databases stores data for benchmarking against the data registered in the register.

In another aspect, the control unit may be connected to the battery management system of the cell pack via a communication interface. The control unit reads the data from the battery management system and registers the data in the register via the communication interface.

In another aspect, the cell pack includes at least one Li-H cell.

In another aspect, the control unit calculates statistical parameters of the data registered in the register and benchmarks the statistical parameters against the data stored in the database.

In another aspect, the result of the benchmarking is taken as the SOH of the cell pack and shown on the display and stored in the database for benchmarking and classification.

Other objectives, advantages and features of the present invention will be apparent from the following description referring to the attached drawings.

### BRIEF DESCRIPTION OF DRAWINGS

The present invention will be described via detailed illustration of the preferred embodiment referring to the drawings wherein:

FIG. 1 is a block diagram of an apparatus for measuring the SOH of a rechargeable Li—H cell pack according to the preferred embodiment of the present invention;

FIG. 2 is a flow chart of a method for operating the apparatus shown in FIG. 1;

FIG. 3 is a chart of data measured in charge of and discharge from a cell pack measured by the apparatus shown in FIG. 1;

FIG. 4 is a chart of the kurtosis of the data shown in FIG. 3;

FIG. 5 is a chart of the skew of the data shown in FIG. 3;

FIG. 6 is a chart of the data shown in FIG. 3 in benchmarked against built-in data of a new cell pack;

FIG. 7 is a chart of the data shown in FIG. 3 for showing a trend of the change in the data; and

FIG. 8 is a chart of the SOH of the cell pack.

### DETAILED DESCRIPTION OF PREFERRED EMBODIMENT

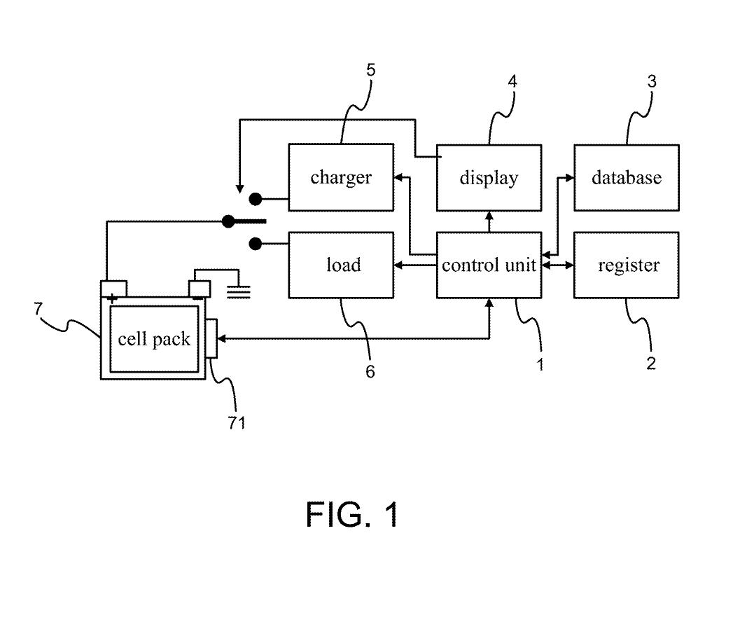

Referring to FIG. 1, there is shown an apparatus for measuring the SOH of a rechargeable Li—H cell pack according to the preferred embodiment of the present invention. The apparatus includes control unit 1, a register 2, a database 3, a display 4, a charger 5 and a load 6. The control unit 1 may be a system-on-chip or a logic circuit. The register 2, the database 3, the display 4, the charger 5 and the load 6 are connected to the control unit 1.

In use, the control unit 1, the display 4, the charger 5 and the load 6 are connected to a cell pack 7 that includes a built-in battery management system (“BMS”) 71. The control unit 1 is preferably connected to the battery management system 71 of the cell pack 7 via a communication interface 11. The cell pack 7 preferably includes Li-H cells.

At 100, the cell pack 7 is charged and made to discharge, and data are read by the BMS 71. The control unit 1 controls the charger 5 to charge the cell pack 7. The control unit 1 controls the load 6 to receive electricity from the cell pack 7. That is, the cell pack 7 discharges to the load 6. The BMS 71 reads the data and registers the data in the register 2.

At S101, the statistical parameters of the data read by the BMS 71 are calculated. The control unit 1 calculates the statistical parameters of the data registered in the register 2.

At S102, the calculated statistical parameters are benchmarked against built-in statistical parameters of the charge of and discharge from a new cell pack. The control unit 1 benches statistical parameters registered in the register 2 against the statistical parameters built in the database 3, regarding the voltage, the current and the temperature.

At S103, the SOH of the cell pack 7 is determined according to a ratio of the statistical parameters. The ratio of the statistical parameters of the data registered in the register 2 over the statistical parameters built in the database 3 is used to calculate the SOH of the cell pack 7. The SOH of the cell pack 7 is shown on the display 4. That is, the aging of the cell pack 7 is determined.

At S104, the cell pack 7 is classified according to the SOH. The SOH of the cell pack 7 is stored in the database 3 so that it can later be used for benchmarking and classification.

Moreover, the calculation of the statistical parameters is done on the outside when the cell pack 7 is charged or made to discharge. Alternatively, the calculation of the statistical parameters is done based on the data sent from the BMS 71. In either case, there is no need to intrude the cell pack 7.

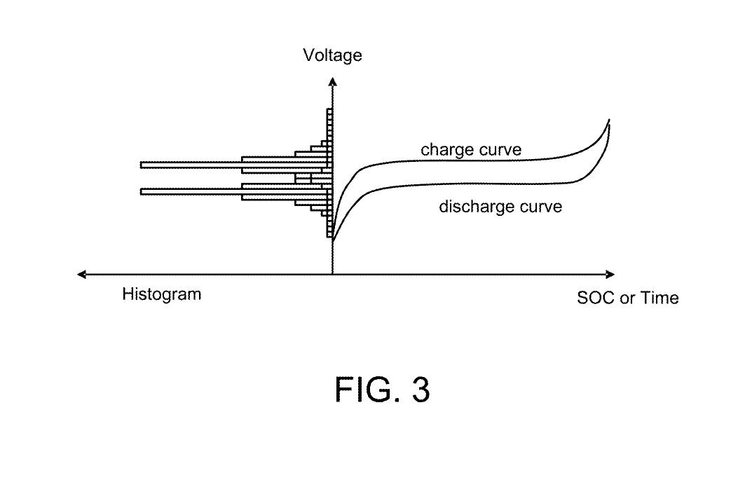

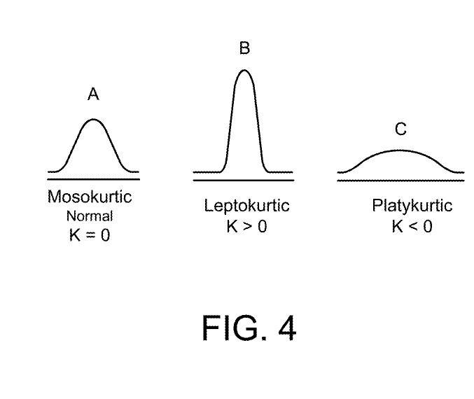

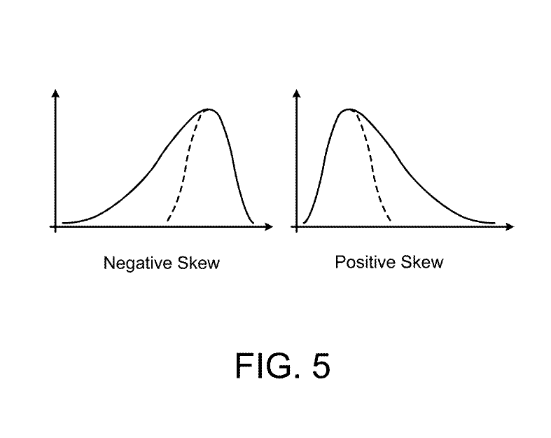

Referring to FIG. 3, the statistical parameters of the data include the mean, the standard deviation, the r-order moment, skew and kurtosis. The kurtosis and skew are shown in FIGS. 4 and 5, respectively.

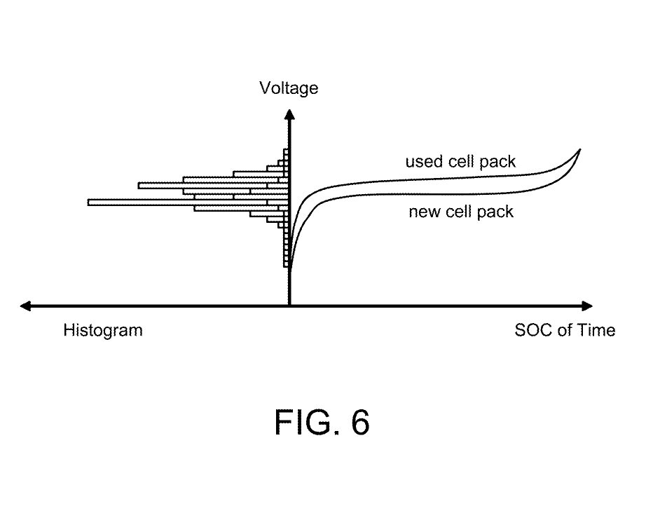

After the cell pack 7 is charged and made to discharge time after time, the data of the charge of and discharge from the cell pack 7 are changed eventually. For example, in the charge of the cell pack, the mean (“μ”) of the measured voltage increases because of the internal impedance, or the standard deviation (“σ”) of the measured voltage increases, as shown in FIG. 6. On the contrary, in the discharge from the cell pack, the mean (“μ”) of the measured voltage increases because of the internal impedance, or the standard deviation (“σ”) of the measured voltage decreases.

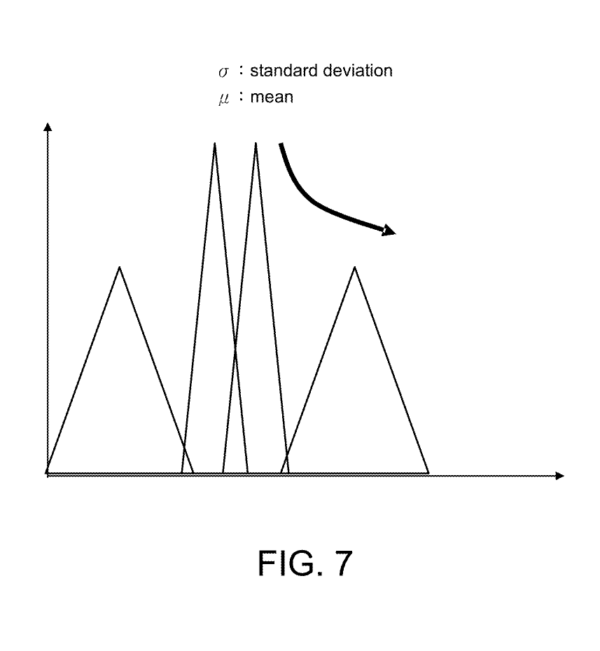

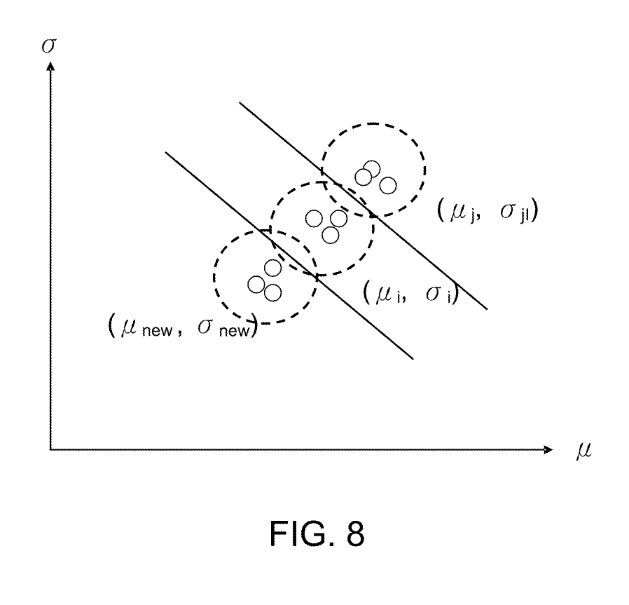

Referring to FIG. 7, there is shown a trend of the change in the data of the charge of and discharge from the pack cell 7. The statistical parameters in the charge tend to move to the right while the statistical parameters in the discharge tend to move to the left. For example, the mean (μ) and the standard deviation (σ) are used as the coordinate axes, and the statistical parameters of the batteries are marked. The statistical parameters of a new cell pack are used as benchmarks for the SOH of the cell pack 7. Referring to FIG. 8, the SOH of the cell pack 7 is shown.

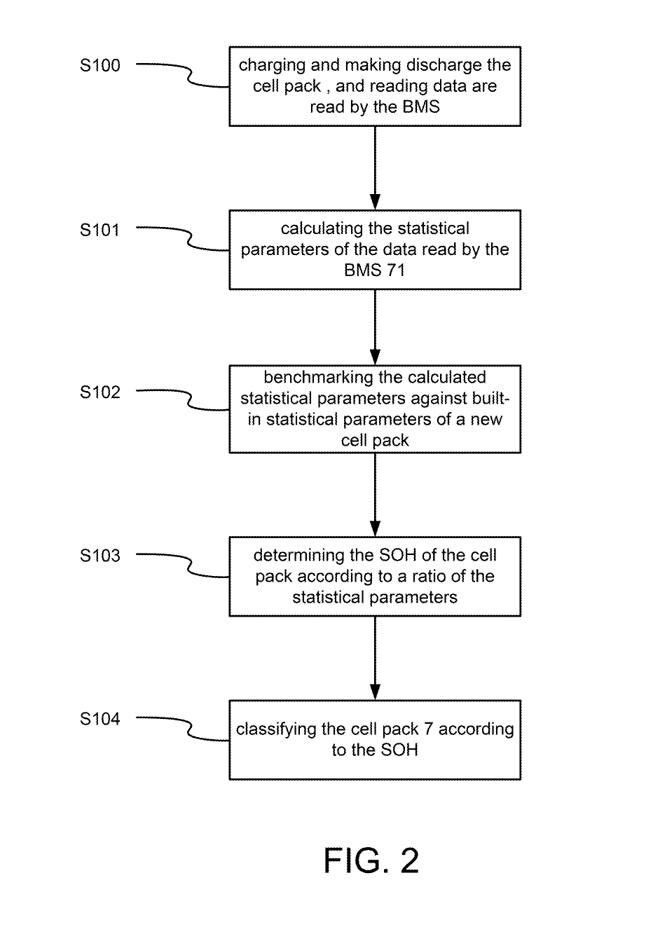

As described above, the apparatus of the present invention is operated in accordance with the flow chart shown in FIG. 2. At first, the cell pack 7 is charged or made to discharge while the BMS 71 collects the data of the charge and discharge. If there is no BMS, the voltage of the cell pack 7 can be measured manually. The data are analyzed to produce the statistical parameters thereof. The statistical parameters of the cell pack 7 are benchmarked against the built-in statistical parameters of a new cell pack. The result of the benchmarking is used as the SOH of the cell pack 7. The cell pack 7 is classified based on the SOH thereof.

As discussed above, the apparatus of the present invention overcomes the drawbacks of the conventional apparatuses addressed in the Related Prior Art. According to the present invention, the register 2, the database 3, the display 4, the charger 5 and the load 6 are connected to the control unit 1.

The data are registered in and read from the register 2 and the database 3. The data provided by the BMS 71 of the cell pack 7 and related to voltage, current and temperature are used to determine the SOH and aging of the cell pack 7. The measurement is not destructive. Therefore, the measurement is inexpensive and safe.

The present invention has been described via the detailed illustration of the preferred embodiment. Those skilled in the art can derive variations from the preferred embodiment without departing from the scope of the present invention. Therefore, the preferred embodiment shall not limit the scope of the present invention defined in the claims.

1. An apparatus for measuring and classifying a cell pack based on statistical parameters of charge of and discharge from the cell pack, wherein the apparatus includes:
a control unit 1;
a register 2 connected to the control unit 1;
a database 3 connected to the control unit 1;
a display 4 connected to the control unit 1;
a charger 5 connected to the control unit 1; and
a load 6 connected to the control unit 1.

2. The apparatus according to claim 1, wherein the control unit, the display, the charger and the load can be connected to the cell pack via a battery management system, wherein the control unit commands the charger to charge the cell pack, commands the load to receive electricity from the cell pack, reads data via the battery management system, and registers the data in the register, wherein the database stores data for benchmarking against the data registered in the register.

3. The apparatus according to claim 2, the control unit is connected to the battery management system of the cell pack via a communication interface, wherein the control unit reads the data from the battery management system and register the data in the register via the communication interface.

4. The apparatus according to claim 2, wherein the cell pack includes at least one Li—H cell.

5. The apparatus according to claim 2, wherein the control unit calculates statistical parameters of the data registered in the register and benchmarks the statistical parameters against the data stored in the database.

6. The apparatus according to claim 5, wherein the result of the benchmarking is taken as the SOH of the cell pack and shown on the display and stored in the database for benchmarking and classification.
